(19) United States
(12) Patent Application Publication
(10) Pub. No.: US 2026/0018198 A1
(43) Pub. Date: Jan. 15, 2026

(54) MAGNETIC MEMORY DEVICE

(71) Applicant: Samsung Electronics Co., Ltd., Suwon-si (KR)

(72) Inventors: Ki Woong KIM, Suwon-si (KR); Jeong Chun RYU, Suwon-si (KR)

(73) Assignee: Samsung Electronics Co., Ltd., Suwon-si (KR)

(21) Appl. No.: 19/047,190

(22) Filed: Feb. 6, 2025

(30) Foreign Application Priority Data
Jul. 10, 2024 (KR) 10-2024-0090872

(51) Int. Cl. G11C 11/16; H10B 61/00; H10N 50/20; H10N 50/85

(52) U.S. Cl. CPC G11C 11/161; H10B 61/22; H10N 50/20; H10N 50/85

(57) ABSTRACT

A magnetic memory device is provided. The magnetic memory device includes a spin orbit layer including a non-magnetic element exhibiting a spin Hall effect, a magnetic tunnel junction layer including a free layer, a tunnel barrier layer, and a pinned layer sequentially stacked on a first surface, the magnetic tunnel junction layer having perpendicular magnetic anisotropy (PMA), and a lower magnetic layer on the second surface, the lower magnetic layer having in-plane magnetic anisotropy (IMA), wherein the free layer includes a first sub-free layer and a second sub-free layer each including a magnetic element, and wherein a first concentration of the magnetic element in the first sub-free layer and a second concentration of the magnetic element in the second sub-free layer are different from each other.

### CROSS-REFERENCE TO RELATED APPLICATION

This application claims priority from Korean Patent Application No. 10-2024-0090872 filed on Jul. 10, 2024, in the Korean Intellectual Property Office, and all the benefits accruing therefrom under 35 U.S.C. 119, the contents of which in its entirety are herein incorporated by reference.

### BACKGROUND

### Technical Field

The present disclosure relates to a magnetic memory device, and more particularly, to a Spin-Orbit Torque-Magnetic Random-Access Memory (SOT-MRAM).

### Description of the Related Art

As demand for electronic devices to become faster and more energy-efficient, the demand for faster read/write operations and lower operating voltages in embedded memory devices also increases. Magnetic memory devices are being researched as memory devices that meet these demands. Magnetic memory devices are non-volatile and capable of operating at high speed, making them promising candidates for next-generation memories.

Meanwhile, as magnetic memory devices become increasingly integrated, Spin-Orbit Torque-Magnetic Random-Access Memories (SOT-MRAMs), which store information using Spin-Orbit Torque (SOT), are being researched. SOT-MRAMs have driving speeds ten times faster than Spin-Transfer Torque-Magnetic Random-Access Memories (STT-MRAMs), and allow stable information storage due to the separate paths for write and read currents.

### SUMMARY

Aspects of the present disclosure provide a magnetic memory device with memristive switching characteristics.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, there is provided a magnetic memory device comprising a spin orbit layer having a first surface and a second surface that are opposite to each other, the spin orbit layer including a non-magnetic element configured to exhibit a spin Hall effect; a magnetic tunnel junction layer including a free layer, a tunnel barrier layer, and a pinned layer sequentially stacked over the first surface, the magnetic tunnel junction layer having perpendicular magnetic anisotropy (PMA); and a lower magnetic layer under the second surface, the lower magnetic layer having in-plane magnetic anisotropy (IMA), wherein the free layer includes at least a first sub-free layer on the first surface and a second sub-free layer that are sequentially stacked over the first sub-free layer, each of the first and second sub-free layers including a magnetic element, and wherein a first concentration of the magnetic element in the first sub-free layer and a second concentration of the magnetic element in the second sub-free layer are different from each other.

According to the aforementioned and other embodiments of the present disclosure, there is provided a magnetic memory device comprising a spin orbit layer having a first surface and a second surface that are opposite to each other, the spin orbit layer including a non-magnetic heavy metal element; and a magnetic tunnel junction layer including a free layer, a tunnel barrier layer, and a pinned layer that are sequentially stacked over the first surface, the magnetic tunnel junction layer having perpendicular magnetic anisotropy (PMA), wherein the free layer includes a plurality of sub-free layers that are sequentially stacked over the spin orbit layer, a magnetic interface layer adjacent to the tunnel barrier layer, and a magnetic coupling layer between the plurality of sub-free layers and the magnetic interface layer, and wherein the plurality of sub-free layers each include cobalt (Co) and the plurality of sub-free layers has a concentration gradient of Co in a vertical direction from the spin orbit layer toward the tunnel barrier layer.

According to the aforementioned and other embodiments of the present disclosure, there is provided a magnetic memory device comprising a spin orbit layer having a first surface and a second surface that are opposite to each other, the spin orbit layer including a non-magnetic heavy metal element; a magnetic tunnel junction layer including a free layer, a tunnel barrier layer, and a pinned layer that are sequentially stacked over the first surface; the magnetic tunnel junction layer having perpendicular magnetic anisotropy (PMA); and a lower magnetic layer under the second surface, the lower magnetic layer including a synthetic antiferromagnet having in-plane magnetic anisotropy (IMA), wherein the free layer includes cobalt (Co), a concentration of Co in the free layer is asymmetric in a vertical direction intersecting the first surface, and the pinned layer includes a synthetic antiferromagnet having PMA.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail example embodiments thereof with reference to the attached drawings, in which:

FIG. 1 is an example circuit diagram illustrating a magnetic memory device according to some embodiments.

FIG. 2 is a schematic perspective view illustrating a unit memory cell of the magnetic memory device according to some embodiments.

FIG. 3 is a schematic cross-sectional view illustrating the magnetic memory device according to some embodiments.

FIG. 4 is a schematic cross-sectional view illustrating the free layer of the magnetic memory device according to some embodiments.

FIGS. 5 and 6 are graphs showing the memristive switching characteristics of the magnetic memory device according to some embodiments.

FIG. 7 is another schematic cross-sectional view illustrating the free layer of a magnetic memory device according to some embodiments.

FIG. 8 is a graph for explaining the free layer of FIG. 7.

FIG. 9 is a schematic cross-sectional view illustrating the free layer of a magnetic memory device according to some embodiments.

FIG. 10 is a schematic cross-sectional view illustrating a magnetic memory device according to some embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. In the drawings, the size of each component may be exaggerated for clarity and convenience of description. Additionally, when the terms “about” or “substantially” are used in this specification in connection with a numerical value and/or geometric terms, it is intended that the associated numerical value includes a manufacturing tolerance (e.g., +10%) around the stated numerical value. Further, regardless of whether numerical values and/or geometric terms are modified as “about” or “substantially,” it will be understood that these values should be construed as including a manufacturing or operational tolerance (e.g., +10%) around the stated numerical values and/or geometry. Additionally, whenever a range of values is enumerated, the range includes all values within the range as if recorded explicitly clearly, and may further include the boundaries of the range. Accordingly, “included in” the range of “X” to “Y” includes all values between X and Y, including X and Y.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present inventive concept.

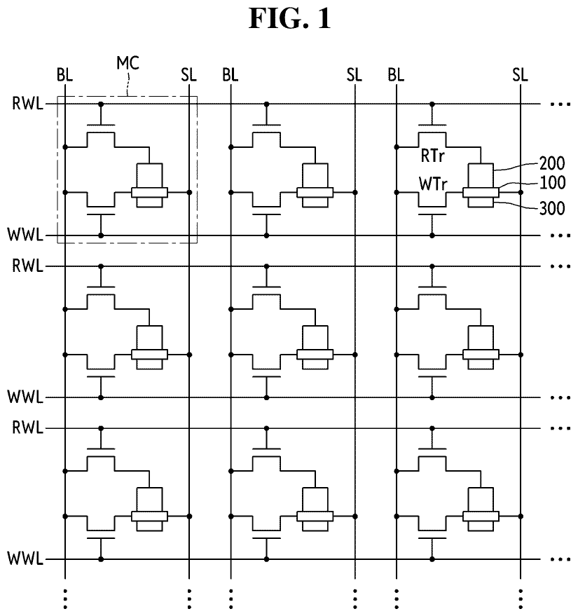

Magnetic memory devices according to some example embodiments will hereinafter be described with reference to FIGS. 1 through 10.

FIG. 1 is an example circuit diagram illustrating a magnetic memory device according to some embodiments.

Referring to FIG. 1, the magnetic memory device according to some embodiments may include a plurality of first wordlines RWL, a plurality of second wordlines WWL, a plurality of bitlines BL, a plurality of source lines SL, and a plurality of unit memory cells MC.

The unit memory cells MC may be arranged two-dimensionally (e.g., in an array) and/or three-dimensionally (e.g., in a stack). The unit memory cells MC may be connected between the first wordlines RWL and the second wordlines WWL, and between the bitlines BL and the source lines SL. Each of the unit memory cells MC may include a spin orbit layer 100, a magnetic tunnel junction layer 200, a lower magnetic layer 300, a first selection element RTr, and a second selection element WTr.

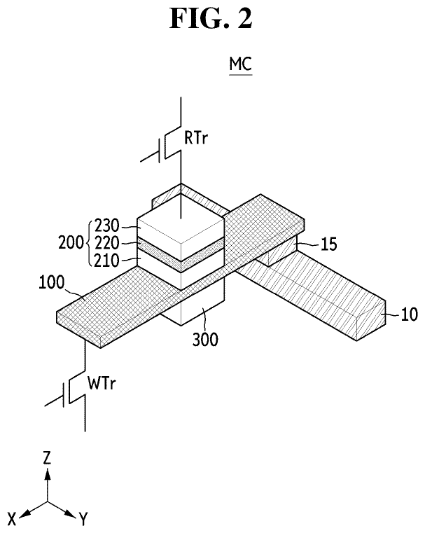

The spin orbit layer 100 may be connected between a source line SL and a bitline BL. The magnetic tunnel junction layer 200 may be disposed on one side of the spin orbit layer 100. The magnetic tunnel junction layer 200 may be connected between the source line SL and the bitline BL. The lower magnetic layer 300 may be disposed on the other side of the spin orbit layer 100. In other words, the spin orbit layer 100 may be interposed between the magnetic tunnel junction layer 200 and the lower magnetic layer 300. The spin orbit layer 100, the magnetic tunnel junction layer 200, and the lower magnetic layer 300 will be described later in detail with reference to FIGS. 2 through 10.

Each of the first and second selection elements RTr and WTr may include at least one of a diode, a PNP bipolar transistor, an NPN bipolar transistor, an N-type metal-oxide semiconductor (NMOS) field-effect transistor (FET), a P-type metal oxide semiconductor (PMOS) FET, a combination thereof, and/or the like.

The first selection element RTr is connected between the magnetic tunnel junction layer 200 and the bitline BL. The first selection element RTr is configured to selectively control the flow of charge passing through the magnetic tunnel junction layer 200. For example, when the first selection element RTr is a transistor, the gate of the first selection element RTr may be connected to a first wordline RWL. The first wordline RWL may be provided as a read line, and may be used to perform a read operation on the corresponding unit memory cell MC.

The second selection element WTr is connected between the spin orbit layer 100 and the bitline BL. The second selection element WTr is configured to selectively control the flow of charge passing through the spin orbit layer 100. For example, when the second selection element WTr is a transistor, the gate of the second selection element WTr may be connected to a second wordline WWL for control. The second wordline WWL may be provided as a write line, and may be used to perform a write operation on the corresponding unit memory cell MC.

FIG. 2 is a schematic perspective view illustrating a unit memory cell of the magnetic memory device according to some embodiments.

Referring to FIGS. 1 and 2, a unit memory cell MC may include the spin orbit layer 100, the magnetic tunnel junction layer 200, and the lower magnetic layer 300. The unit memory cell MC may further include, or be connected to, a conductive line 10.

The spin orbit layer 100 may extend longitudinally in a first direction X. The spin orbit layer 100 may be connected between a second selection element WTr and the conductive line 10. The magnetic tunnel junction layer 200 may be disposed on one surface (e.g., the upper surface) of the spin orbit layer 100. The magnetic tunnel junction layer 200 may be connected between a first selection element RTr and the conductive line 10. The lower magnetic layer 300 may be disposed on another surface (e.g., the lower surface) of the spin orbit layer 100 opposite to the magnetic tunnel junction layer 200.

The conductive line 10 may extend longitudinally in a second direction Y that intersects the first direction X. The conductive line 10 may be connected to one end of the spin orbit layer 100. For example, a conductive via 15, which extends in a third direction Z that intersects the first and second directions X and Y, may be formed to connect the spin orbit layer 100 and the conductive line 10. The conductive line 10 may be provided as (or connected to) a source line (“SL” in FIG. 1).

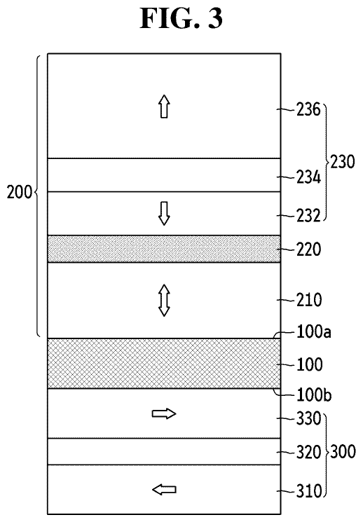

The magnetic tunnel junction layer 200 may include a free layer 210, a tunnel barrier layer 220, and a pinned layer 230, which are sequentially stacked on the spin orbit layer 100. The free layer 210, the tunnel barrier layer 220, and the pinned layer 230 will be described later in detail with reference to FIGS. 3 through 10.

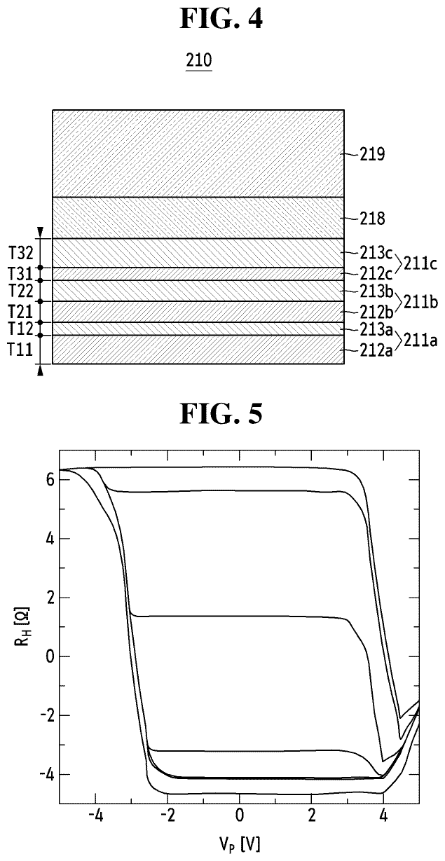

FIG. 3 is a schematic cross-sectional view illustrating the magnetic memory device according to some embodiments. FIG. 4 is a schematic cross-sectional view illustrating the free layer of the magnetic memory device according to some embodiments.

Referring to FIGS. 1 through 4, the magnetic memory device according to some embodiments may include the spin orbit layer 100, the magnetic tunnel junction layer 200, and the lower magnetic layer 300.

The spin orbit layer 100 may include a non-magnetic element that exhibits a spin hall effect based on spin-orbit coupling. For example, the spin orbit layer 100 may include at least one non-magnetic heavy metal element such as platinum (Pt), ruthenium (Ru), tungsten (W), hafnium (Hf), tantalum (Ta), and/or a combination thereof, but the present disclosure is not limited thereto. In some embodiments, the spin orbit layer 100 may include at least one non-magnetic heavy metal element such as Pt, Ru, or W.

The spin orbit layer 100 may include a first surface 100a and a second surface 100b opposite each other. For ease of reference, the first surface 100a may also be referred to as the upper surface of the spin orbit layer 100, and the second surface 100b may also be referred to as the lower surface of the spin orbit layer 100.

The magnetic tunnel junction layer 200 may be disposed on the first surface 100a of the spin orbit layer 100. The magnetic tunnel junction layer 200 may include a free layer 210, a tunnel barrier layer 220, and a pinned layer 230, which are sequentially stacked on the first surface 100a.

The free layer 210 may have a variable magnetization direction. The magnetization direction of the free layer 210 may be variable depending on the spin orbit torque (SOT) caused by the spin current injected from the spin orbit layer 100. For example, the magnetization direction of the free layer 210 may change depending on the direction of the current flowing through the spin orbit layer 100. Additionally, in at least some embodiments, the intensity of the magnetization of the free layer 210 may change depending on duration and intensity of the current flowing through the spin orbit layer 100.

The free layer 210 may include at least one magnetic element. The magnetic element of the free layer 210 may include, for example, cobalt (Co), iron (Fe), nickel (Ni), cobalt-boron (CoB), iron-boron (FeB), nickel-boron (NiB), cobalt-iron (CoFe), nickel-iron (NiFe), and/or a combination thereof, but the present disclosure is not limited thereto. In some embodiments, the magnetic element of the free layer 210 may be Co.

The concentration of the magnetic element (e.g., Co) of the free layer 210 may be asymmetrically configured in a vertical direction intersecting the first surface 100a (e.g., the third direction Z of FIG. 2). For example, the magnetic element of the free layer 210 may have a concentration gradient in the vertical direction. As an example, the Co concentration of the free layer 210 may have a concentration gradient that decreases toward the tunnel barrier layer 220 from the spin orbit layer 100. In another example, the Co concentration of the free layer 210 may have a concentration gradient that increases toward the tunnel barrier layer 220 from the spin orbit layer 100.

In some embodiments, as illustrated in FIG. 4, the free layer 210 may include a plurality of sub-free layers (211a, 211b, and 211c), each containing a magnetic element (e.g., Co). Across the sub-free layers (211a, 211b, and 211c), the concentration of the magnetic element may be asymmetrically configured in the vertical direction. For example, the magnetic element may have a concentration gradient in the vertical direction across the sub-free layers (211a, 211b, and 211c). The number of sub-free layers (211a, 211b, and 211c) illustrated in FIG. 4 is merely example, and the present disclosure is not limited thereto. In some embodiments, the number of stacked sub-free layers (211a, 211b, and 211c) may range from 2 to 10, and/or from 3 to 7.

In some embodiments, the sub-free layers (211a, 211b, and 211c) may include double films of magnetic layers (212a, 212b, and 212c) and non-magnetic layers (213a, 213b, and 213c). For example, the sub-free layers (211a, 211b, and 211c) may include a first sub-free layer 211a, a second sub-free layer 211b, and a third sub-free layer 211c that are sequentially stacked on the first surface 100a of the spin orbit layer 100. For example, the first sub-free layer 211a may include a first magnetic layer 212a and a first non-magnetic layer 213a that are sequentially stacked on the spin orbit layer 100; the second sub-free layer 211b may include a second magnetic layer 212b and a second non-magnetic layer 213b that are sequentially stacked on the first sub-free layer 211a; the third sub-free layer 211c may include a third magnetic layer 212c and a third non-magnetic layer 213c that are sequentially stacked on the second sub-free layer 211b; etc. The sub-free layers (211a, 211b, and 211c) may form multilayer thin films with the magnetic layers (212a, 212b, and 212c) and the non-magnetic layers (213a, 213b, and 213c) alternately stacked along the vertical direction.

The first, second, and third magnetic layers 212a, 212b, and 212c may each include a magnetic metal layer containing a magnetic element. The magnetic element may include, for example, Co, Fe, Ni, CoB, FeB, NiB, CoFe, NiFe, and/or a combination thereof, but the present disclosure is not limited thereto). For example, each of the first, second, and third magnetic layers 212a, 212b, and 212c may include a Co film, an Fe film, an Ni film, a CoB film, an FeB film, an NiB film, a CoFe film, an NiFe film, and/or a combination thereof. In one example, the first, second, and third magnetic layers 212a, 212b, and 212c may each include a Co film.

The first, second, and third non-magnetic layers 213a, 213b, and 213c may each include a non-magnetic metal layer containing a non-magnetic element. The non-magnetic element may include, for example, Pt, palladium (Pd), gold (Au), iridium (Ir), Ru, and/or a combination thereof, but the present disclosure is not limited thereto. For example, each of the first, second, and third non-magnetic layers 213a, 213b, and 213c may include a Pt film, a Pd film, an Au film, an Ir film, an Ru film, a Ta film, a chromium (Cr) film, a niobium (Nb) film, or a combination thereof. In one example, the first, second, and third non-magnetic layers 213a, 213b, and 213c may be Pt films.

In some embodiments, the first, second, and third magnetic layers 212a, 212b, and 212c may have a thickness gradient in the vertical direction, and the first, second, and third non-magnetic layers 213a, 213b, and 213c may have a thickness gradient opposite to that of the first, second, and third magnetic layers 212a, 212b, and 212c in the vertical direction.

For example, in the vertical direction, the first magnetic layer 212a may have a first thickness T11, the first non-magnetic layer 213a may have a second thickness T12, the second magnetic layer 212b may have a third thickness T21, the second non-magnetic layer 213b may have a fourth thickness T22, the third magnetic layer 212c may have a fifth thickness T31, and the third non-magnetic layer 213c may have a sixth thickness T32. In this example, the first thickness T11 may be greater than the third thickness T21, and the fifth thickness T31 may be greater than the third thickness T21. Conversely, the second thickness T12 may be less than the fourth thickness T22, and the fourth thickness T22 may be less than the sixth thickness T32. In this case, the concentration gradient of the magnetic element (e.g., Co) in the free layer 210 may decrease from the spin orbit layer 100 toward the tunnel barrier layer 220.

In some embodiments, the first, third, and fifth thicknesses T11, T21, and T31 of the first, second, and third magnetic layers 212a, 212b, and 212c and the second, fourth, and sixth thicknesses T12, T22, and T32 of the first, second, and third non-magnetic layers 213a, 213b, and 213c may each range from about 0.1 Å to about 20 Å, or from about 1 Å to about 10 Å.

In some embodiments, the thickness of each of the sub-free layers (211a, 211b, and 211c) may be identical or substantially identical. In this specification, the term “identical” encompasses not only being completely identical but also the presence of minor differences (e.g., 5% or less) that may occur due to process margins. For example, the sum of the thicknesses of the first magnetic layer 212a and the first non-magnetic layer 213a, i.e., T11+T12, the sum of the thicknesses of the second magnetic layer 212b and the second non-magnetic layer 213b, i.e., T21+T22, and the sum of the thicknesses of the third magnetic layer 212c and the third non-magnetic layer 213c, i.e., T31+T32, may be identical or substantially identical.

For example, in one embodiment, the first thickness T11 may be about 3 Å, and the second thickness T12 may be about 7 Å; the third and fourth thicknesses T21 and T22 may each be about 5 Å; and the fifth thickness T31 may be about 7 Å, and the sixth thickness T32 may be about 3 Å.

Therefore, referring to FIG. 4, the concentration gradient of the magnetic element (e.g., Co) in the free layer 210 may decrease from the spin orbit layer 100 toward the tunnel barrier layer 220, but the present disclosure is not limited thereto. It may also be understood by one of ordinary skill in the art that the concentration gradient of the magnetic element (e.g., Co) in the free layer 210 may be configured to increase from the spin orbit layer 100 toward the tunnel barrier layer 220.

In some embodiments, the free layer 210 may include a magnetic coupling layer 218 and a magnetic interface layer 219 that are sequentially stacked on the sub-free layers (211a, 211b, and 211c).

The magnetic interface layer 219 may be the uppermost layer of the free layer 210 and may be in contact with the tunnel barrier layer 220. The magnetic interface layer 219 may include a magnetic element that can bond with the oxygen atoms of the tunnel barrier layer 220 to induce interfacial perpendicular magnetic anisotropy (i-PMA). For example, the magnetic interface layer 219 may include at least one of a CoFeB film, a CoB film, an Fe film, a CoFeBSi film, and/or a combination thereof, but the present disclosure is not limited thereto. In some embodiments, the magnetic element of the magnetic interface layer 219 may be, for example, Fe. For example, the magnetic interface layer 219 may include a CoFeB film or a CoFe film. The thickness of the magnetic interface layer 219 may range from about 1 Å to about 20 Å, from about 5 Å to about 15 Å, and/or from about 10 Å to about 12 Å.

The magnetic coupling layer 218 may be interposed between the sub-free layers (211a, 211b, and 211c) and the magnetic interface layer 219. The sub-free layers (211a, 211b, and 211c) and the magnetic interface layer 219 may form ferromagnetic coupling (FC) via the magnetic coupling layer 218. For example, the magnetic coupling layer 218 may include alpha-tungsten (α-W) and/or beta-tungsten (β-W), but the present disclosure is not limited thereto. For example, in some embodiments, a ratio of beta-tungsten (β-W) the magnetic coupled layer 218 may be controlled such that the magnetic coupled layer 218 possesses properties associated with the spin Hall effect associated with the beta-tungsten (β-W) (and not, e.g., with tungsten having, e.g., an alpha (α) phase) without the higher resistivity associated with the beta-tungsten (β-W). In some embodiments, the magnetic coupling layer 218 may include a W film containing at least one impurity element of nitrogen (N), silicon (Si), Ta, titanium (Ti), or a combination thereof. The thickness of the magnetic coupling layer 218 may range from about 0.1 Å to about 5 Å, or from about 1 Å to about 3 Å.

Referring back to FIGS. 1 through 4, the tunnel barrier layer 220 may be interposed between the free layer 210 and the pinned layer 230. The tunnel barrier layer 220 may be provided as an insulated tunnel barrier that is configured to generate quantum mechanical tunneling between the free layer 210 and the pinned layer 230.

The tunnel barrier layer 220 may include magnesium oxide (MgO), aluminum oxide (Al₂O₃), silicon oxide (SiO₂), tantalum oxide (Ta₂O₅), silicon nitride (SiN), aluminum nitride (AlN), and/or a combination thereof, but the present disclosure is not limited thereto. In some embodiments, the tunnel barrier layer 220 may include an MgO film having a face-centered cubic (FCC) crystal structure, or a sodium chloride (NaCl) crystal structure.

The pinned layer 230 may have a fixed magnetization direction. For example, the magnetization direction of the pinned layer 230 may remain fixed regardless of the spin current injected from the spin orbit layer 100 and/or an externally applied magnetic field.

The pinned layer 230 may include a ferromagnetic material. For example, the pinned layer 230 may include an amorphous rare-earth element alloy, a multilayer thin film with alternating layers of ferromagnetic metal (FM) and non-magnetic metal (NM), an alloy with an L10 crystal structure, a Co-based alloy, and/or a combination thereof, but the present disclosure is not limited thereto.

The amorphous rare-earth element alloy may include an alloy such as at least one of TbFe, TbCo, TbFeCo, DyTbFeCo, or GdTbCo. The multilayer thin film with the alternating layers of FM and NM may include a multilayer thin film such as at least one of Co/Pt, Co/Pd, CoCr/Pt, Co/Ru, Co/Os, Co/Au, or Ni/Cu. The alloy with the L10 crystal structure may include an alloy such as, for example, Fe₅₀Pt₅₀, Fe₅₀Pd₅₀, Co₅₀Pt₅₀, Fe₃₀Ni₂₀Pt₅₀, or Co₃₀Ni₂₀Pt₅₀. The Co-based alloy may include an alloy such as, for example, CoCr, CoPt, CoCrPt, CoCrTa, CoCrPtTa, CoCrNb, or CoFeB.

In some embodiments, the magnetic tunnel junction layer 200 may have perpendicular magnetic anisotropy (PMA). That is, the free layer 210 and the pinned layer 230 may each have a magnetization easy axis in the vertical direction (e.g., the third direction Z of FIG. 2). The unidirectional arrows in the pinned layer 230 of FIG. 3 indicate that the magnetization direction of the pinned layer 230 is fixed vertically. Additionally, the bidirectional arrow in the free layer 210 of FIG. 3 indicates that the magnetization direction of the free layer 210 may be magnetized parallel or antiparallel to the magnetization direction of the pinned layer 230.

In some embodiments, the pinned layer 230 may include a synthetic antiferromagnet (SAF) with PMA. For example, the pinned layer 230 may include a first sub-pinned layer 232, a first antiferromagnetic coupling layer 234, and a second sub-pinned layer 236 that are sequentially stacked on the tunnel barrier layer 220. The first and second sub-pinned layers 232 and 236 may exhibit antiferromagnetic coupling (AFC) characteristics through Ruderman-Kittel-Kasuya-Yosida (RKKY) interactions via the first antiferromagnetic coupling layer 234. For example, as illustrated, the magnetization direction of the first sub-pinned layer 232 and the magnetization direction of the second sub-pinned layer 236 may be arranged antiparallel to reduce and/or minimize the overall magnetization of the pinned layer 230.

The first and second sub-pinned layers 232 and 236 may each have a fixed vertical magnetization direction. The first and second sub-pinned layers 232 and 236 may each include a ferromagnetic material (such as an amorphous rare-earth element alloy), a multilayer thin film with alternating layers of FM and NM, an alloy with an L10 crystal structure, a Co-based alloy, and/or a combination thereof. In some embodiments, the first and second sub-pinned layers 232 and 236 may each include at least one of a Co film, a CoPt film, a double layer of a Co film and a Pt film, and/or a multilayer thin film with alternating layers of a Co film and a Pt film.

The first antiferromagnetic coupling layer 234 may be interposed between the first and second sub-pinned layers 232 and 236. The first antiferromagnetic coupling layer 234 may include a non-magnetic material, for example, at least one of Ru, Cr, Pt, Pd, Ir, rhodium (Rh), osmium (Os), rhenium (Re), Au, copper (Cu), and a combination thereof. In some embodiments, the first antiferromagnetic coupling layer 234 may include at least one of an Ir film, a Ru film, a Re film, and a combination thereof.

The lower magnetic layer 300 may be disposed on the second surface 100b of the spin orbit layer 100. The lower magnetic layer 300 may have a fixed magnetization direction. For example, the magnetization direction of the lower magnetic layer 300 may remain fixed regardless of the direction of the current flowing through the spin orbit layer 100 and/or an externally applied magnetic field.

The lower magnetic layer 300 may include a ferromagnetic material, for example, at least one of an amorphous rare-earth element alloy, a multilayer thin film with alternating layers of FM and NM, an alloy with an L10 crystal structure, a cobalt-based alloy, and a combination thereof.

In some embodiments, the lower magnetic layer 300 may have in-plane magnetic anisotropy (IMA). That is, the lower magnetic layer 300 may have a magnetization easy axis in a horizontal direction (e.g., the first direction X or the second direction Y). The unidirectional arrows in the lower magnetic layer 300 of FIG. 3 indicate that the magnetization direction of the lower magnetic layer 300 is fixed horizontally.

In some embodiments, the lower magnetic layer 300 may include a SAF with IMA. For example, the lower magnetic layer 300 may include a third sub-pinned layer 310, a second antiferromagnetic coupling layer 320, and a fourth sub-pinned layer 330 that are sequentially stacked. The third and fourth sub-pinned layers 310 and 330 may exhibit antiferromagnetic coupling (AFC) characteristics through Ruderman-Kittel-Kasuya-Yosida (RKKY) interactions via the second antiferromagnetic coupling layer 320. For example, as illustrated, the magnetization direction of the third sub-pinned layer 310 and the magnetization direction of the fourth sub-pinned layer 330 may be arranged antiparallel to minimize the overall magnetization of the lower magnetic layer 300.

The third and fourth sub-pinned layers 310 and 330 may each have a fixed horizontal magnetization direction. The third and fourth sub-pinned layers 310 and 330 may each include a ferromagnetic material, for example, at least one of an amorphous rare-earth element alloy, a multilayer thin film with alternating layers of FM and NM, an alloy with an L10 crystal structure, a Co-based alloy, and/or a combination thereof. In some embodiments, the third and fourth sub-pinned layers 310 and 330 may each include a Co film, an Fe film, a CoFe film, a CoFeB film, a CoB film, an FeB film, and/or a combination thereof.

The second antiferromagnetic coupling layer 320 may be interposed between the third and fourth sub-pinned layers 310 and 330. The second antiferromagnetic coupling layer 320 may include a non-magnetic material, for example, Ru, Cr, Pt, Pd, Ir, Rh, Os, Re, Au, Cu, and/or a combination thereof. In some embodiments, the second antiferromagnetic coupling layer 320 may include an Ir film, a Ru film, a Re film, and/or a combination thereof.

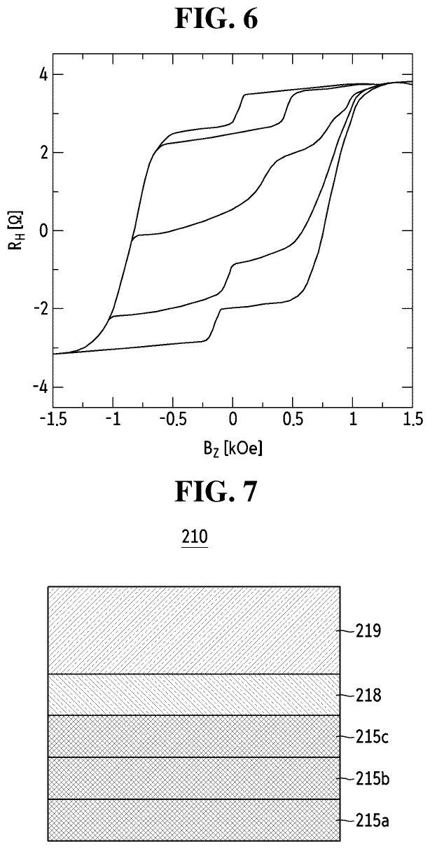

FIGS. 5 and 6 are graphs showing the memristive switching characteristics of the magnetic memory device according to some embodiments. For reference, FIG. 5 shows the Hall Resistance-Pulse Voltage (R_{H}-V_{P}) loop measured by varying the applied current for an SOT-MRAM fabricated according to FIGS. 2 through 4. Additionally, FIG. 6 shows the Hall Resistance-Field (R_{H}-B_{Z}) loop measured by varying the applied current for an SOT-MRAM fabricated according to FIGS. 2 through 4.

Referring to FIGS. 5 and 6, that the magnetic memory device according to some embodiments exhibits memristive switching characteristics, where the resistance value changes according to the applied current, can be confirmed. This can be understood as due to the breaking of symmetry in the free layer 210 in the vertical direction. For example, as described above, as the magnetic element (e.g., Co) in the free layer 210 has a concentration gradient in the vertical direction, gradient-induced bulk or interface symmetry breaking can occur. Through this, spin pumping by the spin orbit layer 100 can be controlled by an external current, providing a magnetic memory device with memristive switching characteristics.

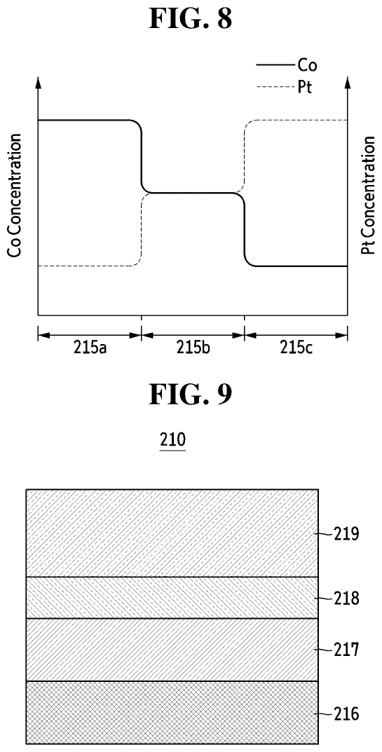

FIG. 7 is another schematic cross-sectional view illustrating the free layer of a magnetic memory device according to some embodiments. FIG. 8 is a graph for explaining the free layer of FIG. 7. For the convenience of explanation, content overlapping with what has been described above with reference to FIGS. 1 through 6 will be briefly explained or omitted.

Referring to FIGS. 3, 7, and 8, in the magnetic memory device according to some embodiments, a free layer 210 may include a plurality of sub-free layers (215a, 215b, and 215c), each containing a magnetic element (e.g., Co).

Across the sub-free layers (215a, 215b, and 215c), the magnetic element may have a concentration gradient in the vertical direction. The number of sub-free layers (215a, 215b, and 215c) illustrated in FIG. 7 is merely example, and the present disclosure is not limited thereto. In some embodiments, the number of stacked sub-free layers (215a, 215b, and 215c) may range from 2 to 10, and/or from 3 to 7.

In some embodiments, each of the sub-free layers (215a, 215b, and 215c) may include an alloy of the magnetic element and a non-magnetic element. For example, the sub-free layers (215a, 215b, and 215c) may include a fourth sub-free layer 215a, a fifth sub-free layer 215b, and a sixth sub-free layer 215c that are sequentially stacked on the first surface 100a of the spin orbit layer 100. The fourth, fifth, and sixth sub-free layers 215a, 215b, and 215c may each include an alloy of the magnetic element and the non-magnetic element.

The magnetic element may include, for example, at least one of Co, Fe, Ni, CoB, FeB, NiB, CoFe, NiFe, and a combination thereof, but the present disclosure is not limited thereto.

The non-magnetic element may include, for example, at least one of Pt, Pd, Au, Ir, Ru, and a combination thereof, but the present disclosure is not limited thereto.

In some embodiments, the fourth, fifth, and sixth sub-free layers 215a, 215b, and 215c may each include a Co-based alloy. For example, the magnetic element may be Co, and the non-magnetic element may include at least one of Pt, Pd, Ta, Cr, Nb, and a combination thereof. In one example, each of the fourth, fifth, and sixth sub-free layers 215a, 215b, and 215c may be CoPt alloy film.

In some embodiments, the magnetic element (e.g., Co) in the fourth, fifth, and sixth sub-free layers 215a, 215b, and 215c may have a concentration gradient in the vertical direction, and the non-magnetic element (e.g., Pt) in the fourth, fifth, and sixth sub-free layers 215a, 215b, and 215c may have a concentration gradient opposite to that of the magnetic element in the vertical direction.

For example, as shown in FIG. 8, a first Co concentration in the fourth sub-free layer 215a may be greater than a second Co concentration in the fifth sub-free layer 215b, and the second Co concentration in the fifth sub-free layer 215b may be greater than a third Co concentration in the sixth sub-free layer 215c. Conversely, a first Pt concentration in the fourth sub-free layer 215a may be less than a second Pt concentration in the fifth sub-free layer 215b, and the second Pt concentration in the fifth sub-free layer 215b may be less than a third Pt concentration in the sixth sub-free layer 215c.

For example, the fourth sub-free layer 215a may include a Co₇Pt₃ film. For example, the fifth sub-free layer 215b may include a Co₅Pt₅ film. For example, the sixth sub-free layer 215c may include a Co₃Pt₇ film.

The thicknesses of the fourth, fifth, and sixth sub-free layers 215a, 215b, and 215c may all be identical or substantially identical, but the present disclosure is not limited thereto. Alternatively, contrary to what is illustrated, the thicknesses of the fourth, fifth, and sixth sub-free layers 215a, 215b, and 215c may be different from one another. In some embodiments, as described above with reference to FIG. 4, the fourth, fifth, and sixth sub-free layers 215a, 215b, and 215c may have a thickness gradient in the vertical direction.

Referring to FIGS. 7 and 8, the concentration gradient of the magnetic element (e.g., Co) in the free layer 210 may decrease from a spin orbit layer 100 toward a tunnel barrier layer 220, but the present disclosure is not limited thereto. It may also be understood by one of ordinary skill in the art that the concentration gradient of the magnetic element (e.g., Co) in the free layer 210 may be configured to increase from the spin orbit layer 100 toward the tunnel barrier layer 220.

FIG. 9 is a schematic cross-sectional view illustrating the free layer of a magnetic memory device according to some embodiments. For the convenience of explanation, content overlapping with what has been described above with reference to FIGS. 1 through 8 will be briefly explained or omitted.

Referring to FIGS. 3 and 9, in the magnetic memory device according to some embodiments, a free layer 210 may include a seventh sub-free layer 216 and an eighth sub-free layer 217, each containing a magnetic element (e.g., Co).

The seventh and eighth sub-free layers 216 and 217 may be sequentially stacked on the first surface 100a of the spin orbit layer 100. Across the seventh and eighth sub-free layers 216 and 217, the magnetic element may have a concentration gradient in the vertical direction. For example, the seventh sub-free layer 216 may include an alloy of the magnetic element and a non-magnetic element, and the eighth sub-free layer 217 may be a magnetic metal layer containing the magnetic element.

In some embodiments, the seventh sub-free layer 216 may include a Co-based alloy. For example, the magnetic element in the seventh sub-free layer 216 may be Co, and the non-magnetic element in the seventh sub-free layer 216 may include at least one of Pt, Pd, Ta, Cr, Nb, and a combination thereof. In one example, the seventh sub-free layer 216 may be a CoPt film, and the eighth sub-free layer 217 may be a Co film.

Referring to FIG. 9, the concentration gradient of the magnetic element (e.g., Co) in the free layer 210 may increase from a spin orbit layer 100 toward a tunnel barrier layer 220, but the present disclosure is not limited thereto. It may also be understood by one of ordinary skill in the art that the concentration gradient of the magnetic element (e.g., Co) in the free layer 210 may be configured to decrease from the spin orbit layer 100 toward the tunnel barrier layer 220.

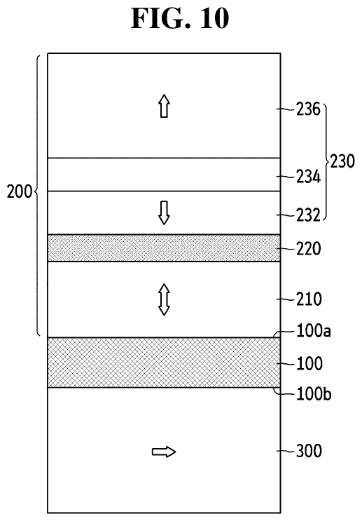

FIG. 10 is a schematic cross-sectional view illustrating a magnetic memory device according to some embodiments. For the convenience of explanation, content overlapping with what has been described above with reference to FIGS. 1 through 9 will be briefly explained or omitted.

Referring to FIG. 10, in the magnetic memory device according to some embodiments, a lower magnetic layer 300 may include a bulk ferromagnet with IMA.

The bulk ferromagnet in the lower magnetic layer 300 may have a magnetization easy axis in the horizontal direction. The unidirectional arrow in the lower magnetic layer 300 of FIG. 10 indicates that the magnetization direction of the lower magnetic layer 300 is fixed horizontally. The bulk ferromagnet may include, for example, a PtMn film or an IrMn film, but the present disclosure is not limited thereto.

While the present inventive concepts have been particularly shown and described with reference to example embodiments thereof, it will be understood by those of ordinary skill in the art that various changes in form and details may be made therein without departing from the spirit and scope of the present inventive concept as defined by the following claims. It is therefore desired that the present embodiments be considered in all respects as illustrative and not restrictive, reference being made to the appended claims rather than the foregoing description to indicate the scope of the invention.

What is claimed is:

1. A magnetic memory device comprising:
a spin orbit layer having a first surface and a second surface that are opposite to each other, the spin orbit layer including a non-magnetic element configured to exhibit a spin Hall effect;
a magnetic tunnel junction layer including a free layer, a tunnel barrier layer, and a pinned layer sequentially stacked over the first surface, the magnetic tunnel junction layer having perpendicular magnetic anisotropy (PMA); and
a lower magnetic layer under the second surface, the lower magnetic layer having in-plane magnetic anisotropy (IMA),
wherein the free layer includes at least a first sub-free layer on the first surface and a second sub-free layer that are sequentially stacked over the first sub-free layer, each of the first and second sub-free layers including a magnetic element, and
wherein a first concentration of the magnetic element in the first sub-free layer and a second concentration of the magnetic element in the second sub-free layer are different from each other.

2. The magnetic memory device of claim 1, wherein the spin orbit layer includes at least one of platinum (Pt), ruthenium (Ru), or tungsten (W).

3. The magnetic memory device of claim 1, wherein the second concentration is less than the first concentration.

4. The magnetic memory device of claim 3, wherein the free layer further includes a third sub-free layer including the magnetic element, between the second sub-free layer and the tunnel barrier layer, and
a third concentration of the magnetic element in the third sub-free layer is less than the second concentration.

5. The magnetic memory device of claim 1, wherein the first sub-free layer includes a first magnetic layer on the first surface and a first non-magnetic layer sequentially stacked over the first magnetic layer,
the second sub-free layer includes a second magnetic layer over the first non-magnetic layer and a second non-magnetic layer sequentially stacked on the second magnetic layer,
each of the first and second magnetic layers includes the magnetic element, and
each of the first and second non-magnetic layers includes a non-magnetic element.

6. The magnetic memory device of claim 5, wherein the second magnetic layer is thinner than the first magnetic layer, and
the second non-magnetic layer is thicker than the first non-magnetic layer.

7. The magnetic memory device of claim 5, wherein
the magnetic element includes at least one of cobalt (Co), iron (Fe), nickel (Ni), cobalt-boron (CoB), iron-boron (FeB), nickel-boron (NiB), cobalt-iron (CoFe), or nickel-iron (NiFe), and
the non-magnetic element includes at least one of platinum (Pt), palladium (Pd), gold (Au), iridium (Ir), or ruthenium (Ru).

8. The magnetic memory device of claim 1, wherein each of the first and second sub-free layers includes an alloy of the magnetic element and a non-magnetic element.

9. The magnetic memory device of claim 8, wherein
the magnetic element includes at least one of Co, Fe, Ni, CoB, FeB, NiB, CoFe, or NiFe, and
the non-magnetic element includes at least one of Pt, Pd, Au, Ir, or Ru.

10. The magnetic memory device of claim 1, wherein the pinned layer includes a synthetic antiferromagnet having PMA.

11. The magnetic memory device of claim 1, wherein the lower magnetic layer includes a synthetic antiferromagnet having IMA.

12. A magnetic memory device comprising:
a spin orbit layer having a first surface and a second surface that are opposite to each other, the spin orbit layer including a non-magnetic heavy metal element; and
a magnetic tunnel junction layer including a free layer, a tunnel barrier layer, and a pinned layer that are sequentially stacked over the first surface, the magnetic tunnel junction layer having perpendicular magnetic anisotropy (PMA),
wherein the free layer includes a plurality of sub-free layers that are sequentially stacked over the spin orbit layer, a magnetic interface layer adjacent to the tunnel barrier layer, and a magnetic coupling layer between the plurality of sub-free layers and the magnetic interface layer, and
wherein the plurality of sub-free layers each include cobalt (Co) and the plurality of sub-free layers has a concentration gradient of Co in a vertical direction from the spin orbit layer toward the tunnel barrier layer.

13. The magnetic memory device of claim 12, wherein the plurality of sub-free layers includes 3 to 7 sub-free layers.

14. The magnetic memory device of claim 12, wherein each of the plurality of sub-free layers includes a cobalt (Co) film and a platinum (Pt) film.

15. The magnetic memory device of claim 12, wherein each of the plurality of sub-free layers includes a cobalt-platinum (CoPt) film.

16. The magnetic memory device of claim 12, wherein the concentration gradient of Co decreases with distances from the spin orbit layer towards the magnetic coupling layer.

17. The magnetic memory device of claim 12, wherein
the tunnel barrier layer includes a magnesium oxide (MgO) film,
the magnetic interface layer includes a cobalt-iron-boron (CoFeB) film, and
the magnetic coupling layer includes a tungsten (W) film.

18. A magnetic memory device comprising:
a spin orbit layer having a first surface and a second surface that are opposite to each other, the spin orbit layer including a non-magnetic heavy metal element;
a magnetic tunnel junction layer including a free layer, a tunnel barrier layer, and a pinned layer that are sequentially stacked over the first surface, the magnetic tunnel junction layer having perpendicular magnetic anisotropy (PMA); and
a lower magnetic layer under the second surface, the lower magnetic layer including a synthetic antiferromagnet having in-plane magnetic anisotropy (IMA),
wherein the free layer includes cobalt (Co),
a concentration of Co in the free layer is asymmetric in a vertical direction intersecting the first surface, and
the pinned layer includes a synthetic antiferromagnet having PMA.

19. The magnetic memory device of claim 18, wherein
the free layer includes a plurality of sub-free layers that are sequentially stacked on the spin orbit layer,
each of the plurality of sub-free layers including Co, and
the asymmetry of the concentration gradient of Co in the vertical direction is a result of a difference in the concentration of Co in the plurality of sub-free layers.

20. The magnetic memory device of claim 19, wherein the free layer further includes
a magnetic interface layer adjacent to the tunnel barrier layer, and
a magnetic coupling layer between the plurality of sub-free layers and the magnetic interface layer, and
wherein the tunnel barrier layer includes a magnesium oxide (MgO) film,
the magnetic interface layer includes a cobalt-iron-boron (CoFeB) film, and
the magnetic coupling layer includes a tungsten (W) film.
